(19) United States
(12) Patent Application Publication
(10) Pub. No.: US 2017/0103958 A1
(43) Pub. Date: Apr. 13, 2017

(54) SEMICONDUCTOR PACKAGE

(71) Applicant: SAMSUNG ELECTRONICS CO., LTD., SUWON-SI (KR)

(72) Inventors: CHANHO LEE, GWANGMYEONG-SI (KR); MYEONG SOON PARK, GOYANG-SI (KR); HYUNSOO CHUNG, HWASEONG-SI (KR)

(21) Appl. No.: 15/213,505

(22) Filed: Jul. 19, 2016

(30) Foreign Application Priority Data
Oct. 8, 2015 (KR) 10-2015-0141754

(51) Int. Cl. H01L 23/00

(52) U.S. Cl. CPC H01L 24/17; H01L 24/06; H01L 23/562; H01L 2224/1712; H01L 2224/17055; H01L 2224/1703; H01L 2224/0903; H01L 2224/09154

(57) ABSTRACT

A semiconductor package includes a semiconductor chip mounted on a substrate that has a top surface and a bottom surface opposite to each other, and connection members that connect the substrate and the semiconductor chip to each other. The connection members include first connection members disposed on a central region of the semiconductor chip and that have heights equal to each other, and second connection members disposed on an edge region of the semiconductor chip and that have heights equal to each other. The heights of the first connection members differ from the heights of the second connection members.

### CROSS-REFERENCE TO RELATED APPLICATION

This application claims priority under 35 U.S.C. §119 from, and the benefit of, Korean Patent Application No. 10-2015-0141754, filed on Oct. 8, 2015, in the Korean Intellectual Property Office, the contents of which are herein incorporated by reference in their entirety.

### BACKGROUND

Embodiments of the inventive concepts are directed to a semiconductor package and, more particularly, to a semiconductor package that includes connection members having different sizes.

When a semiconductor package is manufactured, a semiconductor chip may be mounted on a printed circuit board by a flip-chip bonding method. Flip-chip bonding electrically and physically connects a chip to a printed circuit board (PCB) by structures such as bumps disposed therebetween. In this case, input/output (I/O) pads may be arranged on an entire portion of one surface of the semiconductor chip. Thus, the flip-chip bonding method may be applied to an electronic product (e.g., a microprocessor or a central processing unit (CPU)) needing a large number of I/O pads. In addition, the flip-chip bonding method may shorten electrical connection lengths in a semiconductor package, thereby improving electrical and mechanical characteristics of the semiconductor package.

However, coefficients of thermal expansion (CTE) of the PCB and the chip may differ from each other, which may cause warping of the PCB and the chip. The warping in the chip may be affected by a size of the chip. A pad may not be connected to the bump by the warping in a bonding process, and thus an electrical short may occur by contact with an adjacent bump, or a non-wetting phenomenon may occur. As lighter and thinner semiconductor packages are being manufactured, a warping of semiconductor packages may occur.

### SUMMARY

Embodiments of the inventive concepts can provide connection members capable of compensating warping of a semiconductor chip.

Embodiments of the inventive concepts can also provide a semiconductor package that includes connection members on a bottom surface of a semiconductor chip with different sizes.

According to an embodiment of the inventive concept, a semiconductor package includes a semiconductor chip mounted on a substrate and having a top surface and a bottom surface opposite to the top surface, and connection members connecting the substrate and the semiconductor chip to each other. The connection members include first connection members disposed on a central region of the semiconductor chip and having heights equal to each other, and second connection members disposed on an edge region of the semiconductor chip and having heights equal to each other. The heights of the first connection members differ from the heights of the second connection members.

In some embodiments, the semiconductor chip is warped so that the bottom surface of the semiconductor chip is concave, and the heights of the first connection members are greater than the heights of the second connection members.

In some embodiments, the semiconductor chip is warped so that the top surface of the semiconductor chip is concave, and the heights of the first connection members are less than the heights of the second connection members.

In some embodiments, the connection members further include third connection members disposed on a middle region disposed between the central region and the edge region and having heights equal to each other. The heights of the third connection members differ from the heights of the first connection members and the heights of the second connection members.

In some embodiments, each first connection member includes a first pillar in contact with the bottom surface of the semiconductor chip, and a first solder that connects the first pillar to the substrate. Each second connection member includes a second pillar in contact with the bottom surface of the semiconductor chip, and a second solder that connects the second pillar to the substrate.

In some embodiments, the semiconductor chip is warped so that the bottom surface of the semiconductor chip is concave, and heights of the first pillars are greater than heights of the second pillars.

In some embodiments, the semiconductor chip is warped so that the top surface of the semiconductor chip is concave, and heights of the first pillars are less than heights of the second pillars.

In some embodiments, the first connection members are symmetrically disposed with respect to the center of the semiconductor chip, and the second connection members are symmetrically disposed with respect to the center of the semiconductor chip.

According to another embodiment of the inventive concept, a semiconductor package includes a semiconductor chip mounted on a substrate and having a top surface and a bottom surface opposite to the top surface, and connection members provided between the substrate and the semiconductor chip that connect the substrate and the semiconductor chip to each other. The connection members include first connection members disposed on a central region of the semiconductor chip that have first contact areas with the semiconductor chip that are equal to each other, and second connection members disposed on an edge region of the semiconductor chip that have second contact areas with the semiconductor chip. The first contact areas of the first connection members differ from the second contact areas of the second connection members, and the second contact areas of the second connection members vary as a function of distance from a center of the semiconductor chip.

In some embodiments, the semiconductor chip is warped so that the bottom surface of the semiconductor chip is concave, and the first contact areas of the first connection members is greater than the second contact areas of the second connection members.

In some embodiments, contact areas of the second connection members monotonically decrease from the central region toward an edge of the semiconductor chip.

In some embodiments, the semiconductor chip is warped so that the top surface of the semiconductor chip is concave, and the first contact areas of the first connection members are less than the second contact areas of the second connection members.

In some embodiments, the second contact areas of the second connection members monotonically increase from the central region toward an edge of the semiconductor chip.

In some embodiments, the first connection members are symmetrically disposed with respect to a center of the semiconductor chip, and the second connection members are symmetrically disposed with respect to the center of the semiconductor chip.

In some embodiments, the connection members further include third connection members disposed on a middle region positioned between the central region and the edge region and having third contact areas equal to each other. The third contact areas of the third connection members differ from the first contact areas of the first connection members and the second contact areas of the second connection members.

According to another embodiment of the inventive concept, a semiconductor package includes a semiconductor chip mounted on a substrate, the semiconductor chip having a top surface and a bottom surface opposite to the top surface, and a plurality of connection members that connect the substrate to the bottom surface of the semiconductor chip. Each connection member has a height and a contact area with the semiconductor chip, and the height of the connection member exponentially increases as the contact area of the connection member increases.

In some embodiments, the semiconductor chip is warped such that an edge region of the semiconductor chip is displaced in a direction perpendicular to the top surface or the bottom surface of the semiconductor chip from a tangent plane of a center of the semiconductor chip by an amount greater than a center region of the semiconductor chip, and the heights of the connection members vary as a function of increasing distance from the center of the semiconductor chip.

In some embodiments, the semiconductor chip is warped so that the bottom surface of the semiconductor chip is concave, and the heights of the connection members monotonically decrease with increasing distance from the center of the semiconductor chip.

In some embodiments, the semiconductor chip is warped so that the top surface of the semiconductor chip is concave, and the heights of the connection members monotonically increase with increasing distance from the center of the semiconductor chip.

In some embodiments, the plurality of connection members are symmetrically disposed with respect to a center of the semiconductor chip.

### BRIEF DESCRIPTION OF THE DRAWINGS

FIG. 1 is a plan view that illustrates a semiconductor package according to some embodiments of the inventive concepts.

FIG. 2 is a cross-sectional view taken along a line A-A′ of FIG. 1.

FIG. 3 is a cross-sectional view that illustrates a semiconductor chip and connection members according to some embodiments of the inventive concepts.

FIG. 4 is a plan view that illustrates a semiconductor package according to some embodiments of the inventive concepts.

FIG. 5 is a cross-sectional view taken along a line B-B′ of FIG. 4.

FIG. 6 is a cross-sectional view that illustrates a semiconductor chip and connection members according to some embodiments of the inventive concepts.

FIG. 7 is a plan view that illustrates a semiconductor package according to some embodiments of the inventive concepts.

FIG. 8 is a cross-sectional view taken along a line C-C′ of FIG. 7.

FIG. 9 is a cross-sectional view that illustrates a semiconductor chip and connection members according to some embodiments of the inventive concepts.

FIG. 10 is a plan view that illustrates a semiconductor package according to some embodiments of the inventive concepts.

FIG. 11 is a cross-sectional view taken along a line D-D′ of FIG. 10.

FIG. 12 is a cross-sectional view that illustrates a semiconductor chip and connection members according to some embodiments of the inventive concepts.

FIG. 13 is a graph that illustrates heights of connection members as a function of the areas of the connection members.

FIGS. 14 to 17 are plan views that illustrate semiconductor packages according to some embodiments of the inventive concepts.

### DETAILED DESCRIPTION OF EXAMPLE EMBODIMENTS

Embodiments of the inventive concepts will now be described more fully hereinafter with reference to the accompanying drawings, in which example embodiments of the inventive concepts are shown. The embodiments of the inventive concept may, however, be embodied in different forms and should not be constructed as limited to the embodiments set forth herein.

It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present

Example embodiments of the present inventive concepts explained and illustrated herein include their complementary counterparts. The same reference numerals or the same reference designators may denote the same elements throughout the specification.

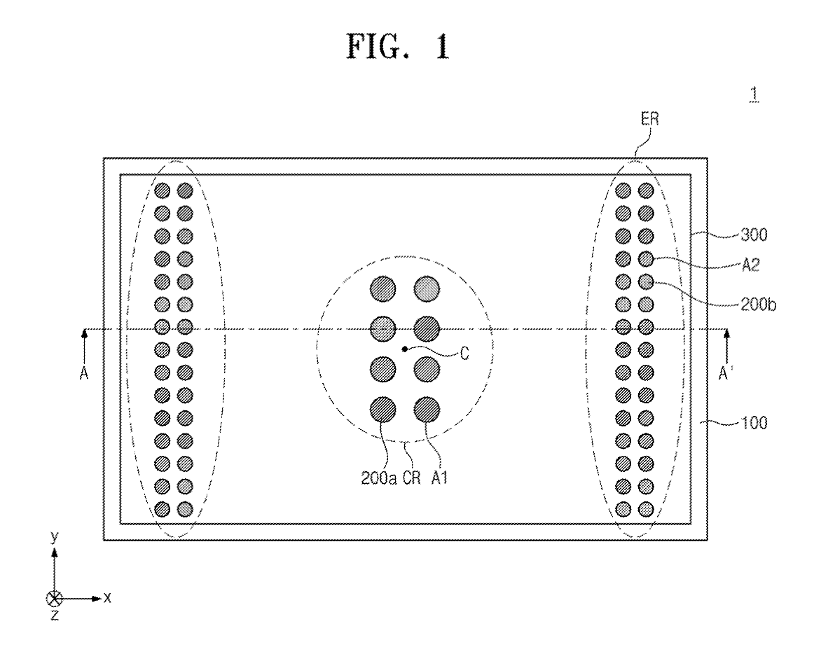

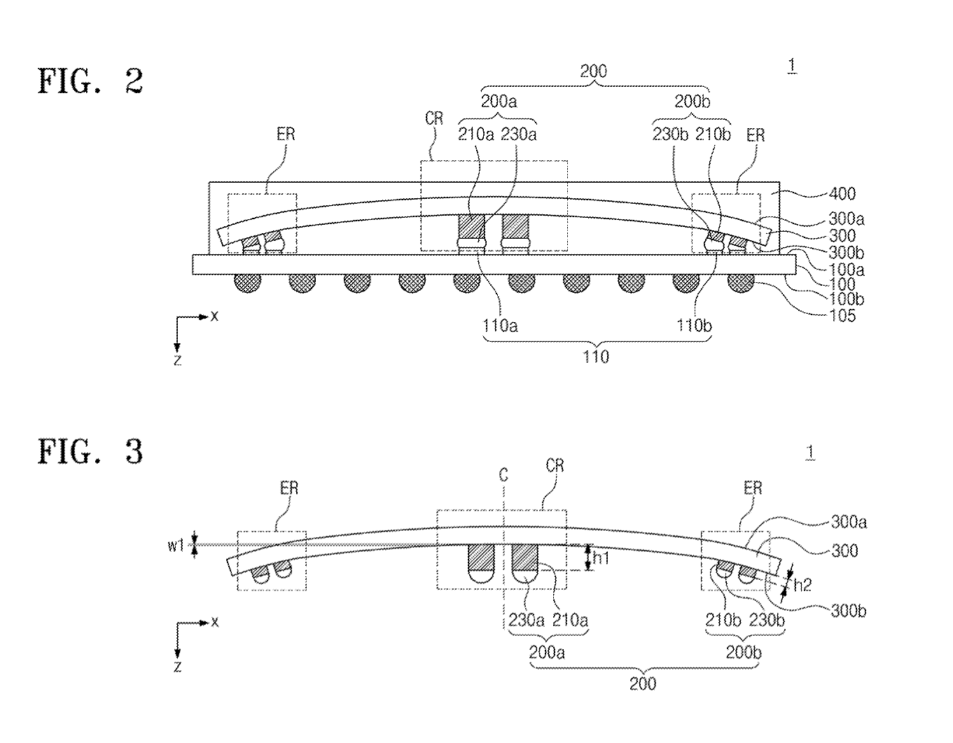

FIG. 1 is a plan view that illustrates a semiconductor package according to some embodiments of the inventive concepts. FIG. 2 is a cross-sectional view taken along a line A-A′ of FIG. 1. FIG. 3 is a cross-sectional view that illustrates a semiconductor chip and connection members according to some embodiments of the inventive concepts.

Referring to FIGS. 1 to 3, a semiconductor package 1 according to some embodiments of the disclosure may include a substrate 100, connection members 200, a semiconductor chip 300, and a mold layer 400. The mold layer 400 may be provided on the substrate 100 to cover the semiconductor chip 300. The mold layer 400 may include an epoxy molding compound (EMC) material.

According to some embodiments, the substrate 100 may be a printed circuit board (PCB) having a top surface 100a and a bottom surface 100b opposite to the top surface 100b. The substrate 100 may have a rectangular shape with sides extending in a first direction x and a second direction y perpendicular to the first direction x. External terminals 105, such as solder balls, may be provided on the bottom surface 100b of the substrate 100, and connection pads 110 may be provided on the top surface 100a of the substrate 100. The connection pads 110 may include first connection pads 110a and second connection pads 110b.

According to some embodiments, the semiconductor chip 300 may have a top surface 300a and a bottom surface 300b opposite to the top surface 300a and that faces the top surface 100a of the substrate 100. The semiconductor chip 300 may be mounted on the substrate 100 by a flip-chip bonding method. The semiconductor chip 300 may include a memory chip, a logic chip, or a combination thereof.

According to some embodiments, the semiconductor chip 300 may include a central region CR and edge regions ER opposite to each other with the central region CR interposed therebetween. The central region CR and the edge regions ER of the semiconductor chip 300 may be characterized by a first warping length w1 from a plane tangent to the center C of the semiconductor chip 300 in a third direction z perpendicular to the bottom surface 300b of the semiconductor chip 300. The central region CR may be warped in the third direction z from the tangent plane of the center C of the semiconductor chip 300 by a distance less than the first warping length w1. The edge region ER may be warped in the third direction z from the tangent plane of the center C of the semiconductor chip 300 by a distance greater than or equal to the first warping length w1. An exemplary, non-limiting value for the first warping length w1 may be 4 μm. In this case, warping of the central region CR in the third direction z may be less than 4 μm, and warping of the edge region ER in the third direction z may be greater than 4 μm.

According to some embodiments, the connection members 200 may be disposed between substrate 100 and the semiconductor chip 300. The connection members 200 may be provided on the bottom surface 300b of the semiconductor chip 300. The connection members 200 may electrically connect the semiconductor chip 300 to the substrate 100. The connection members 200 may include first connection members 200a disposed on the central region CR of the semiconductor chip 300 and second connection members 200b disposed on the edge region ER of the semiconductor chip 300. The first connection members 200a may all have the same size, and the second connection members 200b may all have the same size. The sizes of the first connection members 200a may differ from the sizes of the second connection member 200b. The first connection members 200a may be disposed symmetrically with respect to the center C of the semiconductor chip 300. The second connection members 200b may constitute two groups that are opposite to each other in the first direction x with respect to the center C of the semiconductor chip 300. The second connection members 200b of each group may be spaced apart from each other in the second direction y perpendicular to the first direction x. In other words, the second connection members 200b of each group may be form a plurality of columns in the second direction y.

According to embodiments, the contact area of the connection members 200 refers to the area of contact between the connection members 200 and the bottom surface 300b of the semiconductor chip 300. In some embodiments, contact areas of the first connection members 200a may differ from those of the second connection members 200b when viewed from a plan view. Each first connection member 200a may have a first contact area A1, and each second connection member 200b may have a second contact area A2. Here, the first contact area A1 may be greater than the second contact area A2.

In some embodiments, heights of the first connection members 200a may differ from heights of the second connection members 200b. Each first connection member 200a may include a first pillar 210a in contact with the bottom surface 300b of the semiconductor chip 300, and a first solder 230a that connects the first pillar 210a to the first connection pad 110a on the substrate 100. Each of the second connection members 200b includes a second pillar 210b in contact with the bottom surface 300b of the semiconductor chip 300 and a second solder 230b that connects the second pillar 210b to the second connection pad 110b on the substrate 100. The first pillars 210a may have a first height h1, and the second pillars 210b may have a second height h2. In some embodiments, the first height h1 may be greater than the second height h2. A size of the first solder 230a may be greater than that of the second solder 230b. The relationships between the sizes of the pillars 210a and 210b and the sizes of the solders 230a and 230b will be described below.

In some embodiments, the first and second pillars 210a and 210b may include a metal having a melting point that is higher than that of the first and second solders 230a and 230b. For example, the first and second pillars 210a and 210b may include copper (Cu), and the first and second solders 230a and 230b may include an alloy that includes at least one of tin (Sn), silver (Ag), copper (Cu), nickel (Ni), bismuth (Bi), indium (In), antimony (Sb), or cerium (Ce).

In some embodiments, the contact area and the height of the first connection member 200a may differ from the contact area and the height of the second connection member 200b, respectively.

Since the semiconductor package 1 includes various materials, such as silicon, metal, and solder-resist, having different coefficients of thermal expansion (CTE), the semiconductor package 1 may warp due to external heating or self-heating. The semiconductor chip 300 may warp such that the bottom surface 300b of the semiconductor chip 300 becomes concave. In other words, the semiconductor package 1 may include semiconductor chip 300 having negative warpage. Negative warpage means that the semiconductor chip 300 is warped such that the bottom surface 300b is concave.

When the warped semiconductor chip 300 is mounted on the substrate 100, the connection members 200 may not properly couple to the connection pads 110 of the substrate 100, thereby causing defects, such as non-contact between the connection member 200 and the connection pad 110, or contact between connection members 200. However, according to some embodiments of the inventive concepts, relatively large first connection members 200a may be disposed in the central region CR of the semiconductor chip 300, and relatively small second connection members 200b may be disposed in the edge region ER of the semiconductor chip 300. Thus, defects due to the warped semiconductor chip 300 may be compensated. As a result, the semiconductor chip 300 may be mounted on the substrate 100 without defects.

In addition, if the sizes of all the connection members 200 differ from each other, a process of bonding the connection members 200 to the bottom surface 300b of the semiconductor chip 300 may be complex. However, according to some embodiments of the inventive concepts, the sizes of the first connection members 200a may all be equal, the sizes of the second connection members 200b may all be equal, and the sizes of the first connection members 200a may differ from the sizes of the second connection members 200b. Thus, a process of bonding the connection members 200 to the bottom surface 300b of the semiconductor chip 300 can be easily performed.

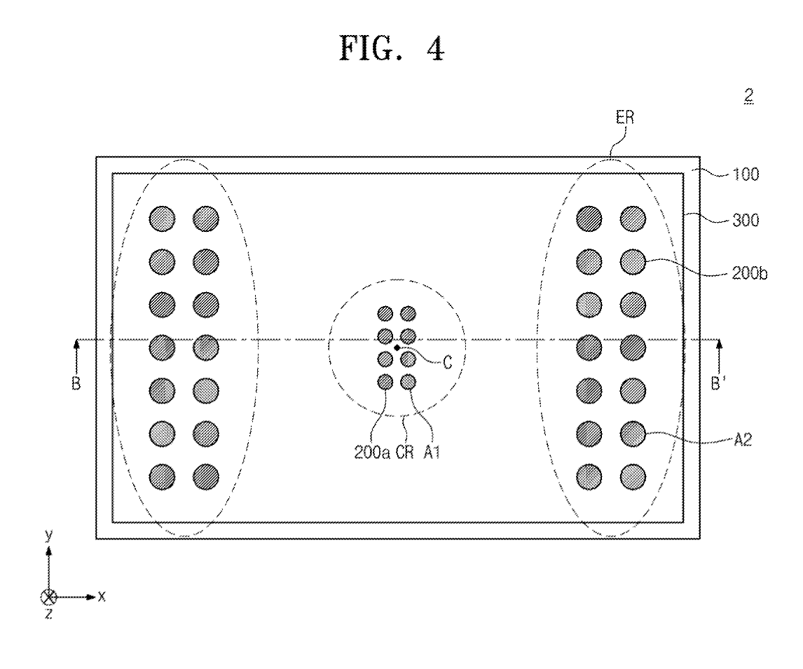

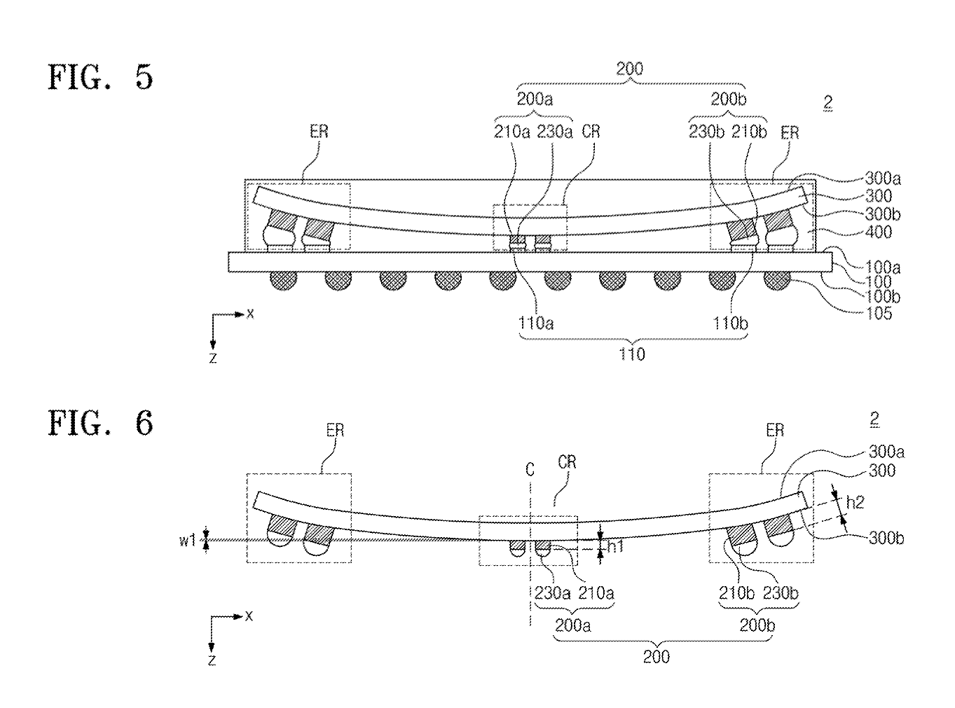

FIG. 4 is a plan view that illustrates a semiconductor package according to some embodiments of the inventive concepts. FIG. 5 is a cross-sectional view taken along a line B-B′ of FIG. 4. FIG. 6 is a cross-sectional view that illustrates a semiconductor chip and connection members according to some embodiments of the inventive concepts. Hereinafter, for convenience of explanation, descriptions of the same technical features as in the above embodiments will be mentioned briefly or omitted.

Referring to FIGS. 4 to 6, a semiconductor package 2 according to some embodiments of the disclosure may include the substrate 100, connection members 200, the semiconductor chip 300, and the mold layer 400. The mold layer 400 may be provided on the substrate 100 to cover the semiconductor chip 300. The mold layer 400 may include an epoxy molding compound (EMC) material.

Since the semiconductor package 2 includes various materials, such as silicon, metal, and solder-resist, having different coefficients of thermal expansion (CTE), the semiconductor package 2 may be warped due to external heating or self-heating. The semiconductor chip 300 may be warped such that the top surface 300a of the semiconductor chip 300 is concave. In other words, the semiconductor package 2 may include semiconductor chip 300 having positive warpage. Positive warpage means that the semiconductor chip 300 is warped such that the top surface 300a is concave.

In some embodiments, the semiconductor chip 300 may include a central region CR and edge regions ER opposite each other with the central region CR interposed therebetween. The central region CR and the edge regions ER of the semiconductor chip 300 may be characterized by a first warping length w1 from a plane tangent to the center C of the semiconductor chip 300 in a third direction z perpendicular to the top surface 300a of the semiconductor chip 300. The central region CR may be warped in the third direction z from the tangent plane of the center C of the semiconductor chip 300 by a distance less than the first warping length w1. The edge region ER may be warped in the third direction z from the tangent plane of the center C of the semiconductor chip 300 by a distance greater than or equal to the first warping length w1. An exemplary, non-limiting value for the first warping length w1 may be 4 μm. In this case, warping of the central region CR in the third direction z may be less than 4 μm, and warping of the edge region ER in the third direction z may be greater than 4 μm.

In some embodiments, connection members 200 having different sizes may be provided on the bottom surface 300b of the semiconductor chip 300 to compensate the positive warpage of the semiconductor chip 300. Contact areas of the first connection members 200a may differ from those of the second connection members 200b when viewed from a plan view. Each first connection members 200 may have a first contact area A1, and each second connection member 200b may have a second contact area A2. Here, the second area A2 may be greater than the first area A1.

In some embodiments, heights of the first connection members 200a may differ from heights of the second connection members 200b. Each first connection member 200a may include the first pillar 210a having a first height h1, and each second connection member 200b may include the second pillar 210b having a second height h2. The second height h2 may be greater than the first height h1. A size of the second solder 230b may be greater than that of the first solder 230a. The relationships between the sizes of the pillars 210a and 210b and the sizes of the solders 230a and 230b will be described below.

In some embodiments, the contact area and the height of the first connection member 200a may differ from the contact area and the height of the second connection member 200b, respectively.

According to some embodiments of the inventive concepts, relatively small first connection members 200a may be disposed in the central region CR of the semiconductor chip 300, and relatively large second connection members 200b may be disposed in the edge region ER of the semiconductor chip 300. Thus, the semiconductor chip 300 may be mounted on the substrate 100 without defects. The sizes of the first connection members 200a may all be equal and the sizes of the second connection members 200b may all be equal. Thus, a process of bonding the connection members 200 to the bottom surface 300b of the semiconductor chip 300 can be easily performed.

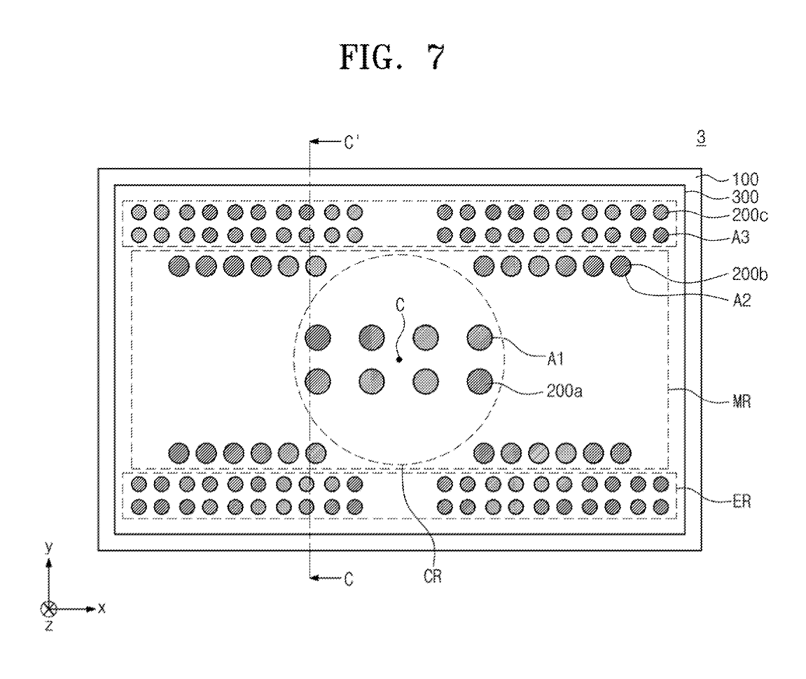

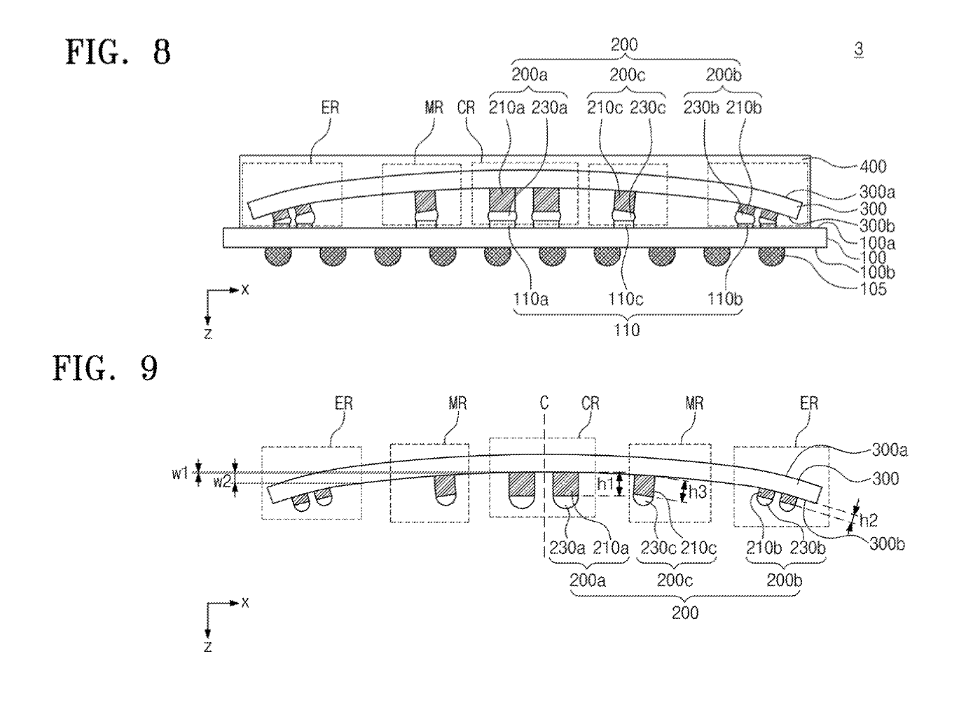

FIG. 7 is a plan view that illustrates a semiconductor package according to some embodiments of the inventive concepts. FIG. 8 is a cross-sectional view taken along a line C-C′ of FIG. 7. FIG. 9 is a cross-sectional view that illustrates a semiconductor chip and connection members according to some embodiments of the inventive concepts. Hereinafter, for convenience of explanation, descriptions of the same technical features as in the above embodiments will be mentioned briefly or omitted.

Referring to FIGS. 7 to 9, a semiconductor package 3 according to some embodiments may include a warped the semiconductor chip 300 with a concave bottom surface 300b. The semiconductor chip 300 may be mounted on the substrate 100. The substrate 100 may include external terminals 105 disposed on its bottom surface 100b and the connection pads 110 on its top surface 100a. The connection pads 110 may include first connection pads 110a, second connection pads 110b, and third connection pads 110c.

According to some embodiments, the semiconductor chip 300 may be divided into a central region CR, a middle region MR, and edge regions ER. The middle region MR may be symmetric with respect to the central region CR, and the edge regions ER may also be symmetric with respect to the central region CR. For example, the middle region MR may surround the central region CR, and the edge regions ER may include two regions opposite each other in the second direction y with the middle region MR interposed therebetween. The central region CR may be warped in the third direction z from the tangent plane of the center C of the semiconductor chip 300 by a distance less than a first length w1, and the edge region ER may be warped in the third direction z from the tangent plane of the center C of the semiconductor chip 300 by a distance greater than or equal to a second length w2. The middle region MR may be warped in the third direction z from the tangent plane of the center C of the semiconductor chip 300 by a distance greater than or equal to the first length w1 and less than the second length w2. Exemplary, non-limiting values for the first length w1 and the second length w2 may be 3 μm and 4 μm, respectively. In other words, warping of the central region CR in the third direction z may be less than 3 μm, warping of the middle region MR in the third direction z may be greater than or equal to 3 μm and less than 4 μm, and warping of the edge region ER in the third direction z may be greater than 4 μm.

According to some embodiments, the connection members 200 may be disposed on the bottom surface 300b of the semiconductor chip 300. The connection members 200 may include first connection members 200a in the central region CR, second connection members 200b in the edge region ER, and third connection members 200c in the middle region MR. The first connection members 200a may be symmetrically disposed in two groups above and below the center C of the semiconductor chip 300. In some embodiments, the groups may be rows of first connection members 200a extending in the first x direction above and below the center C of the semiconductor chip 300. The second connection members 200b may include four groups that are opposite each other in the first direction x and the second direction y with respect to the center C of the semiconductor chip 300. Each of the four groups of second connection members 200b may be disposed near a corner of the middle region MR. In some embodiments, each group may be a row of second connection members 200b extending in the first x direction near a corner of the middle region MR. The third connection members 200c may include four groups that are opposite each other in the first direction x and the second direction y with respect to the center C of the semiconductor chip 300. Each of the four groups of third connection members 200c may be disposed at opposite ends of the respective end region ER. In some embodiments, each group may include a plurality of rows of third connection members 200c extending in the first x direction at opposite ends of the respective end region ER.

According to some embodiments, each first connection member 200a may have a first contact area A1, each second connection member 200b may have a second contact area A2, and each third connection member 200c may have a third contact area A3. The first contact area A1 may be greater than the second contact area A2 and the third contact area A3, and the third contact area A3 may be greater than the second contact area A2.

According to some embodiments, each first connection member 200a may include a first pillar 210a in contact with the bottom surface 300b of the semiconductor chip 300, and a first solder 230a connecting the first pillar 210a to the first connection pad 110a on the substrate 100. Each second connection member 200b may include a second pillar 210b in contact with the bottom surface 300b of the semiconductor chip 300, and a second solder 230b connecting the second pillar 210b to the second connection pad 110b on the substrate 100. Each third connection member 200c may include a third pillar 210c in contact with the bottom surface 300b of the semiconductor chip 300, and a third solder 230c connecting the third pillar 210c to the third connection pad 110c on the substrate 100. The first, second and third pillars 210a, 210b and 210c may include a metal having a melting point that is higher than that of the first, second and third solders 230a, 230b and 230c. For example, the first to third pillars 210a, 210b and 210c may include copper (Cu), and the first to third solders 230a, 230b and 230c may include an alloy that includes at least one of tin (Sn), silver (Ag), copper (Cu), nickel (Ni), bismuth (Bi), indium (In), antimony (Sb), or cerium (Ce).

According to some embodiments, the first pillars 210a may have a first height h1, the second pillars 210b may have a second height h2, and the third pillars 210c may have a third height h3. The first height h1 may be greater than the second height h2 and the third height h3, and the third height h3 may be greater than the second height h2. A size of the first solder 230a may be greater than that of the second solder 230b and that of the third solder 230c. The size of third solder 230c may be greater than that of the second solder. The relationships between the sizes of the pillars 210a, 210b and 210c and the sizes of the solders 230a, 230b and 230c will be described below.

In some embodiments, the areas and the heights of the first, second and third connection members 200a, 200b and 200c may differ from each other, respectively.

According to some embodiments of the inventive concepts, if the semiconductor chip 300 is relatively greatly warped, three types of connection members 200 having different sizes may be provided on the bottom surface 300b of the semiconductor chip 300. Sizes of the connection members 200 may decrease stepwise from the center C toward the edge of the semiconductor chip 300, and thus the semiconductor chip 300 warped in the third direction z may be mounted on the substrate 100 without defects.

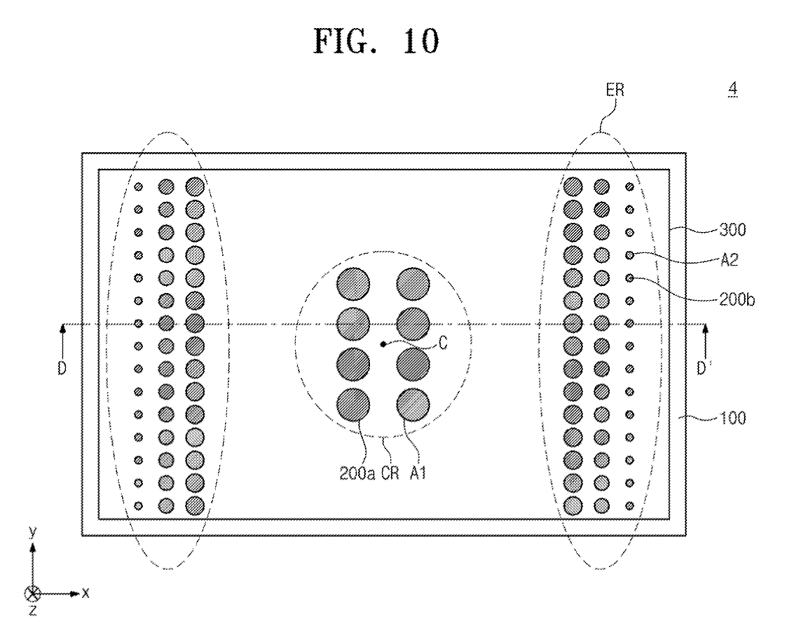

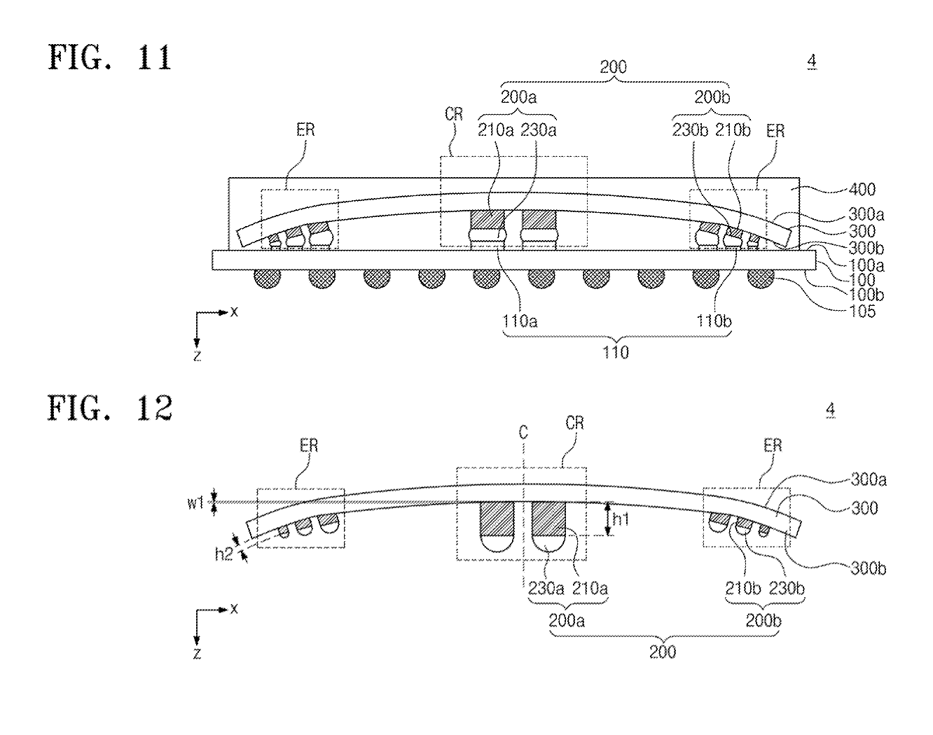

FIG. 10 is a plan view that illustrates a semiconductor package according to some embodiments of the inventive concepts. FIG. 11 is a cross-sectional view taken along a line D-D′ of FIG. 10. FIG. 12 is a cross-sectional view that illustrates a semiconductor chip and connection members according to some embodiments of the inventive concepts. Hereinafter, for convenience of explanation, descriptions of the same technical features as in the above embodiments will be mentioned briefly or omitted.

Referring to FIGS. 10 to 12, a semiconductor package 4 according to some embodiments may include a warped semiconductor chip 300 with a concave bottom surface 300b. The semiconductor chip 300 may be mounted on the substrate 100. The substrate 100 may include the external terminals 105 disposed on its bottom surface 100b and the connection pads 110 on its top surface 100a. The connection pads 110 may include first connection pads 110a and second connection pads 110b.

According to some embodiments, the semiconductor chip 300 may be divided into the central region CR and the edge regions ER. The edge regions ER may be symmetric with respect to the central region CR. For example, the edge regions ER may be opposite each other in the first direction x with the middle region MR interposed therebetween. The central region CR may be warped in the third direction z from the tangent plane of the center C of the semiconductor chip 300 by a distance less than a first length w1, and the edge region ER may be warped in the third direction z from the tangent plane of the center C of the semiconductor chip 300 by a distance greater than or equal to the first length w1. An exemplary, non-limiting value for the first length w1 may be 4 μm. In other words, warping of the central region CR in the third direction z may be less than 4 μm, and warping of the edge region ER in the third direction z may be greater than 4 μm.

According to some embodiments, the connection members 200 may be disposed on the bottom surface 300b of the semiconductor chip 300. The connection members 200 may include first connection members 200a disposed on the central region CR and second connection members 200b disposed on the edge region ER. The first connection members 200a may be symmetrically disposed in two groups about the center C of the semiconductor chip 300. In some embodiments, the groups may be columns of first connection members 200a extending in the second 7 direction. The second connection members 200b may include two groups that are opposite each other in the second direction y with respect to the center C of the semiconductor chip 300. In some embodiments, each group may include a plurality of columns of second connection members 200b extending in the first y direction.

According to some embodiments, sizes of the first connection members 200a may be equal to each other. Sizes of the second connection members 200b may vary as a function of distance from the center C of the semiconductor chip 300. For example, sizes of the second connection members 200b may monotonically decrease from the central region CR toward an edge of the semiconductor chip 300.

According to some embodiments, each first connection member 200a may have a first contact area A1, and each second connection member 200b may have a second contact area A2. The first contact areas A1 may be greater than the second contact areas A2. The second contact areas A2 may be varied as a function of distance from the center C of the semiconductor chip 300. For example, the second contact areas A2 may monotonically decrease from the central region CR toward the edge of the semiconductor chip 300.

According to some embodiments, each of the first connection member 200a may include a first pillar 210a in contact with the bottom surface 300b of the semiconductor chip 300 and a first solder 230a connecting the first pillar 210a to the first connection pad 110a on the substrate 100. Each second connection member 200b may include a second pillar 210b in contact with the bottom surface 300b of the semiconductor chip 300 and a second solder 230b connecting the second pillar 210b to the second connection pad 110b on the substrate 100. The first and second pillars 210a and 210b may include a metal having a melting point that is higher than that of the first and second solders 230a and 230b. For example, the first and second pillars 210a and 210b may include copper (Cu), and the first and second solders 230a and 230b may include an alloy that includes at least one of tin (Sn), silver (Ag), copper (Cu), nickel (Ni), bismuth (Bi), indium (In), antimony (Sb), or cerium (Ce).

According to some embodiments, the first pillars 210a may have a first height h1 and the second pillars 210b may have second height h2. The first height h1 may be greater than the second height h2. The second height h2 may varie as a function of a distance from the center C of the semiconductor chip 300. For example, the second heights h2 of the second pillars 210b may monotonically decrease from the center region CR to the edge of the semiconductor chip 300. A size of the first solder 230a may be greater than that of the second solder 230b. The relationships between the sizes of the pillars 210a and 210b and the sizes of the solders 230a and 230b will be described below.

In some embodiments, the area and the height of the first connection member 200a may differ from the area and the height of the second connection member 200b, respectively.

According to some embodiments of the inventive concepts, the second connection members 200b may be provided on the bottom surface 300b of the semiconductor chip 300. Since the connection members 200 are disposed on the bottom surface 300b of the semiconductor chip 300, the semiconductor chip 300 warped in the third direction z may be mounted on the substrate 100 without defects.

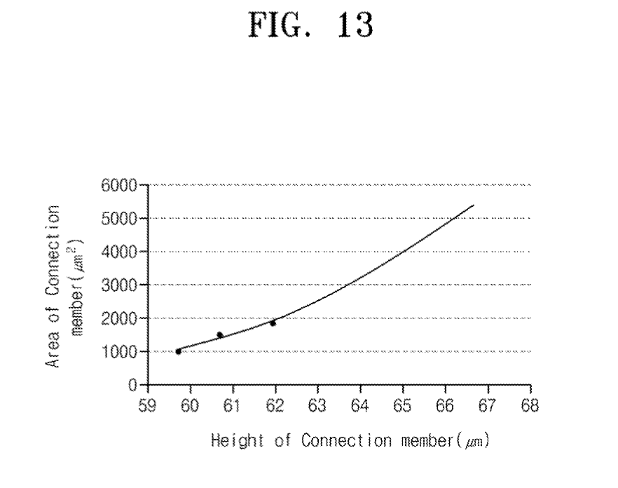

FIG. 13 is a graph that illustrates heights of connection members as a function of the areas of the connection members.

Referring to FIGS. 1, 3, 4, 6, 7, 9, 10, 12 and 13, an x-axis represents the heights of the connection members 200 and a y-axis represents the contact areas of the connection members 200 in the graph of FIG. 13. Here, the l contact areas of the connection members 200 may be the contact areas of the pillars 210a, 210b and 210c.

The graph of FIG. 13 represents relation between the contact areas of the connection members 200 and the heights of the connection members 200 before the semiconductor chip 300 is mounted on the substrate 100. The relation between the contact areas and the heights can be expressed by the equation y=3e⁻²³x^{14.367}, where y is the contact area of the connection member 200 and x is the height of the connection member 200. The height of the connection member 200 may exponentially increase as the contact area of the pillars 210a, 210b and 210c increases. Since the height of each of the connection members 200 is a sum of the height of each of the pillars 210a, 210b and 210c and a height of each of the solders 230a, 230b and 230c, the sizes of the solders 230a, 230b and 230c may increase as the contact areas of the pillars 210a, 210b and 210c increase. Thus, as the contact areas of the connection members 200 increase, the sizes of the solders 230a, 230b and 230c may also increase.

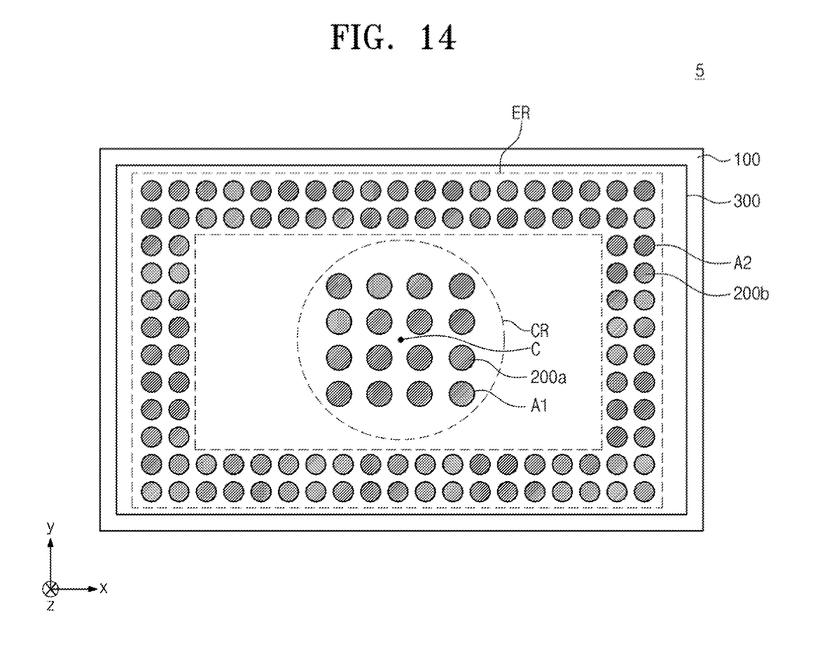

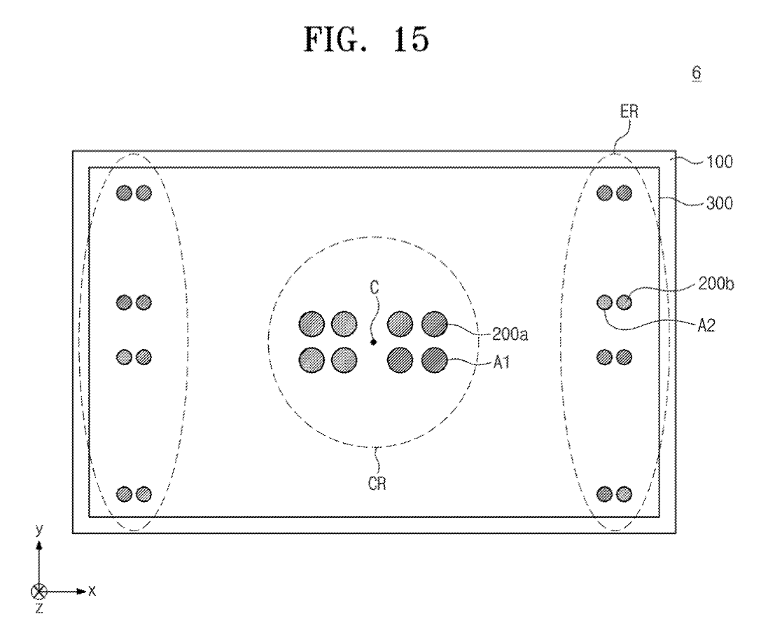

FIGS. 14 to 17 are plan views that illustrate semiconductor packages according to some embodiments of the inventive concepts. Hereinafter, for convenience of explanation, the descriptions of the same technical features as in the above embodiments will be mentioned briefly or omitted.

Referring to FIG. 14, a semiconductor package 5 according to some embodiments may include first connection members 200a provided on the central region CR of the semiconductor chip 300 and second connection members 200b provided on the edge region ER of the semiconductor chip 300. The second connection members 200b may be disposed to surround the first connection members 200a. The second connection members 200b may be arranged along the edge of the semiconductor chip 300 and may form a plurality of columns. Each of the first connection members 200a may have a first contact area A1, and each of the second connection members 200b may have a second contact area A2. The first contact area A1 may be greater than the second contact area A2.

Referring to FIG. 15, a semiconductor package 6 according to some embodiments may include first connection members 200a provided on the central region CR of the semiconductor chip 300 and second connection members 200b provided on the edge regions ER of the semiconductor chip 300. The second connection members 200b may be disposed opposite each other in the first direction x with the center C of the semiconductor chip 300 interposed therebetween. Groups of the second connection members 200b of each edge region CR may be spaced apart from each other in the second direction y. Each first connection member 200a may have a first contact area A1, and each second connection member 200b may have a second contact area A2. The first contact area A1 may be greater than the second contact area A2.

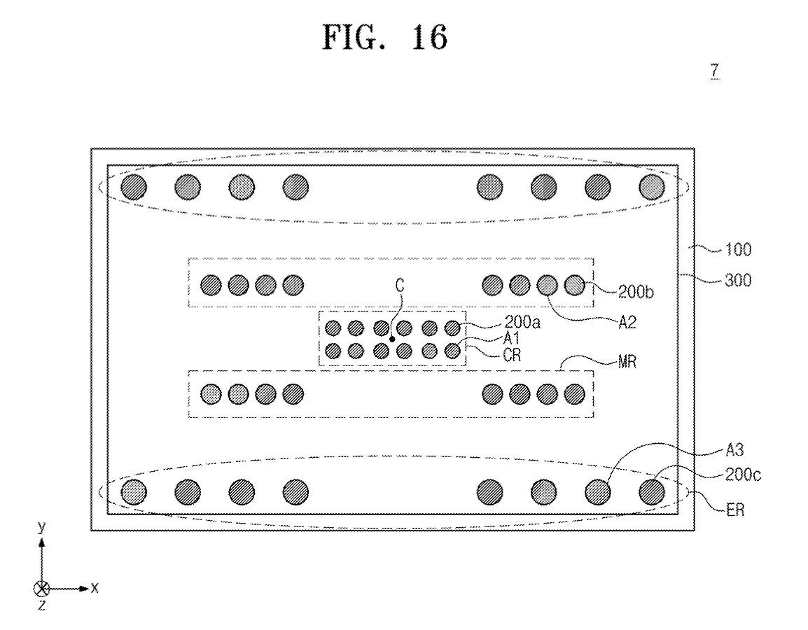

Referring to FIG. 16, a semiconductor package 7 according to some embodiments may include first connection members 200a provided on a central region CR of the semiconductor chip 300, second connection members 200b provided on edge regions ER of the semiconductor chip 300, and third connection members 200c provided on middle regions MR of the semiconductor chip 300. Each first connection member 200a may have a first contact area A1, each second connection member 200b may have a second contact area A2, and each third connection member 200c may have a third contact area A3. The second contact area A2 may be greater than the first contact area A1 and the third contact area A3, and the third contact area A3 may be greater than the first contact area A1. In other words, the contact areas of the connection members 200 may increase stepwise toward the edge of the semiconductor chip 300.

The connection members 200 may be disposed symmetrically with respect to the center C of the semiconductor chip 300. In some embodiments, the middle region MR may include two regions above and below the central region CR, and the edge regions ER may include two regions opposite each other in the second direction y with the middle region MR interposed therebetween. The first connection members 200a may be symmetrically disposed in two groups above and below the center C of the semiconductor chip 300. In some embodiments, each group may be a row of first connection members 200a extending in the first x direction. The second connection members 200b may include four groups that are opposite each other in the first direction x and the second direction y with respect to the center C of the semiconductor chip 300. Each of the four groups of second connection members 200b may be disposed at opposite ends of a respective middle region MR. In some embodiments, each group may be a row of second connection members 200b extending in the first x direction. The third connection members 200c may include four groups that are opposite each other in the first direction x and the second direction y with respect to the center C of the semiconductor chip 300. Each of the four groups of third connection members 200c may be disposed at opposite ends of the respective end region ER. In some embodiments, each group may be a row of third connection members 200c extending in the first x direction.

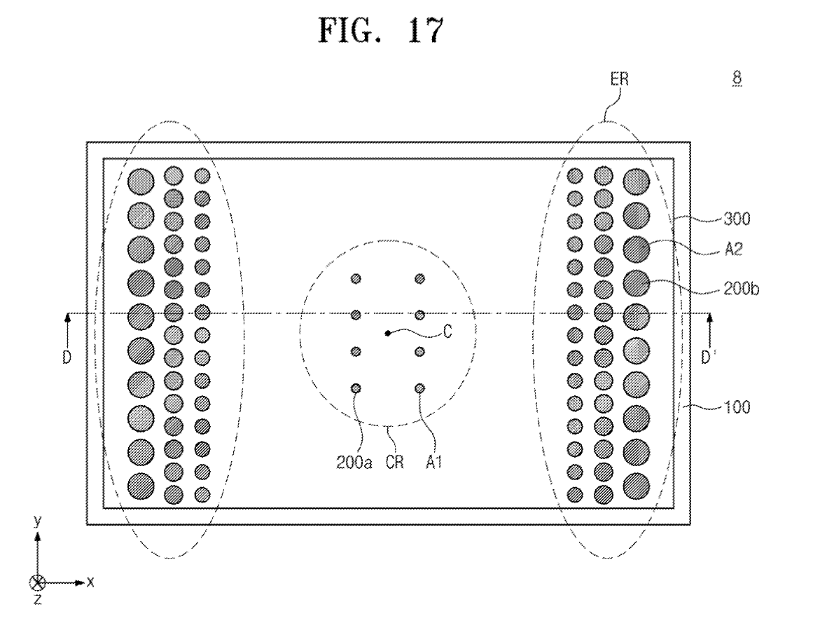

Referring to FIG. 17, a semiconductor package 8 according to some embodiments may include first connection members 200a provided on the central region CR of the semiconductor chip 300 and second connection members 200b provided on the edge regions ER of the semiconductor chip 300. The second connection members 200b may be disposed opposite each other in the first direction x with respect to the center C of the semiconductor chip 300. The second connection members 200b may form a plurality of columns in the second direction y. Each first connection member 200a may have a first contact area A1, and each second connection member 200b may have a second contact area A2. The second contact area A2 may be greater than the first contact area A1. The second contact area A2 may vary according to a distance from the center C of the semiconductor chip 300. For example, the second contact areas A2 of the second connection members 200b monotonically may increase toward the edge of the semiconductor chip 300.

The arrangements of the connection members 200 provided on the bottom surface 300b of the semiconductor chip 300 are not limited to the embodiments described above. In some embodiments, the connection members 200 may not be symmetric with respect to the center C of the semiconductor chip 300, based on warping of the semiconductor chip 300.

In addition, the sizes of the connection members 200 provided on the bottom surface 300b of the semiconductor chip 300 are not limited to the embodiments described above. In some embodiments, sizes of the connection members 200 may monotonically decrease or increase from the center C toward the edge of the semiconductor chip 30.

According to some embodiments of the inventive concepts, a warped semiconductor chip may be mounted on a substrate without defects.

According to some embodiments of the inventive concepts, connection members having various shapes may be provided according to a magnitude and shape of the warping of a semiconductor chip. Thus, a semiconductor chip may be connected to a substrate without defects.

While embodiments of the inventive concepts have been described with reference to example embodiments, it will be apparent to those skilled in the art that various changes and modifications may be made without departing from the spirits and scopes of the example embodiments of the inventive concepts. Therefore, it should be understood that the above example embodiments are not limiting, but illustrative. Thus, the scope of the embodiments of the inventive concepts are to be determined by the broadest permissible interpretation of the following claims and their equivalents, and shall not be restricted or limited by the foregoing description.

What is claimed is:

1. A semiconductor package comprising:
a semiconductor chip mounted on a substrate, the semiconductor chip having a top surface and a bottom surface opposite to the top surface; and
connection members that connect the substrate and the semiconductor chip to each other,
wherein the connection members comprise:
first connection members disposed on a central region of the semiconductor chip, the first connection members having heights equal to each other; and
second connection members disposed on an edge region of the semiconductor chip, the second connection members having heights equal to each other,
wherein heights of the first connection members differ from heights of the second connection members.

2. The semiconductor package of claim 1, wherein the semiconductor chip is warped so that the bottom surface of the semiconductor chip is concave, and
the heights of the first connection members are greater than the heights of the second connection members.

3. The semiconductor package of claim 1, wherein the semiconductor chip is warped so that the top surface of the semiconductor chip is concave, and
the heights of the first connection members are less than the heights of the second connection members.

4. The semiconductor package of claim 1, wherein the connection members further comprise:
third connection members disposed on a middle region disposed between the central region and the edge region, the third connection members having heights equal to each other,
wherein heights of the third connection members differ from the heights of the first connection members and the heights of the second connection members.

5. The semiconductor package of claim 1, wherein each first connection member comprises: a first pillar contact with the bottom surface of the semiconductor chip; and a first solder that connects the first pillar to the substrate, and
wherein each second connection member comprises: a second pillar in contact with the bottom surface of the semiconductor chip; and a second solder that connects the second pillar to the substrate.

6. The semiconductor package of claim 5, wherein the semiconductor chip is warped so that the bottom surface of the semiconductor chip is concave, and
wherein heights of the first pillars are greater than heights of the second pillars.

7. The semiconductor package of claim 5, wherein the semiconductor chip is warped so that the top surface of the semiconductor chip is concave, and
wherein heights of the first pillars are less than heights of the second pillars.

8. The semiconductor package of claim 1, wherein the first connection members are symmetrically disposed with respect to a center of the semiconductor chip, and the second connection members are symmetrically disposed with respect to the center of the semiconductor chip.

9. A semiconductor package comprising:
a semiconductor chip mounted on a substrate, the semiconductor chip having a top surface and a bottom surface opposite to the top surface; and
connection members provided between the substrate and the semiconductor chip that connect the substrate and the semiconductor chip to each other,
wherein the connection members comprise:
first connection members disposed on a central region of the semiconductor chip, that have first contact areas with the semiconductor chip that are equal to each other; and
second connection members disposed on an edge region of the semiconductor chip that have second contact areas with the semiconductor chip,
wherein the first contact areas of the first connection members differ from the second contact areas of the second connection members, and
wherein the second contact areas of the second connection members vary as a function of distance from a center of the semiconductor chip.

10. The semiconductor package of claim 9, wherein the semiconductor chip is warped so that the bottom surface of the semiconductor chip is concave, and
wherein the first contact areas of the first connection members are greater than the second contact areas of the second connection members.

11. The semiconductor package of claim 9, wherein the second contact areas of the second connection members monotonically decrease from the central region toward an edge of the semiconductor chip.

12. The semiconductor package of claim 9, wherein the semiconductor chip is warped so that the top surface of the semiconductor chip is concave, and
wherein the first contact areas of the first connection members are less than the second contact areas of the second connection members.

13. The semiconductor package of claim 9, wherein the second contact areas of the second connection members monotonically increase from the central region toward an edge of the semiconductor chip.

14. The semiconductor package of claim 9, wherein the first connection members are symmetrically disposed with respect to a center of the semiconductor chip, and the second connection members are symmetrically disposed with respect to the center of the semiconductor chip.

15. The semiconductor package of claim 9, wherein the connection members further comprise:
third connection members disposed on a middle region positioned between the central region and the edge region, the third connection members having third contact areas with the semiconductor chip that are equal to each other,
wherein the third contact areas of the third connection members differ from the first contact areas of the first connection members and the second contact areas of the second connection members.

16. A semiconductor package comprising:
a semiconductor chip mounted on a substrate, the semiconductor chip having a top surface and a bottom surface opposite to the top surface; and
a plurality of connection members that connect the substrate to the bottom surface of the semiconductor chip,
wherein each connection member has a height and a contact area with the semiconductor chip, and the height of the connection member exponentially increases as the contact area of the connection member increases.

17. The semiconductor package of claim 16, wherein the semiconductor chip is warped such that an edge region of the semiconductor chip is displaced in a direction perpendicular to the top surface or the bottom surface of the semiconductor chip from a tangent plane of a center of the semiconductor chip by an amount greater than a center region of the semiconductor chip, and
the heights of the connection members vary as a function of increasing distance from the center of the semiconductor chip.

18. The semiconductor package of claim 17, wherein the semiconductor chip is warped so that the bottom surface of the semiconductor chip is concave, and
the heights of the connection members monotonically decrease with increasing distance from the center of the semiconductor chip.

19. The semiconductor package of claim 17, wherein the semiconductor chip is warped so that the top surface of the semiconductor chip is concave, and
the heights of the connection members monotonically increase with increasing distance from the center of the semiconductor chip.

20. The semiconductor package of claim 16, wherein the plurality of connection members are symmetrically disposed with respect to a center of the semiconductor chip.
